(19) United States
(12) Patent Application Publication
(10) Pub. No.: US 2019/0181327 A1
(43) Pub. Date: Jun. 13, 2019

(54) ELECTROSTATIC TRANSDUCER

(71) Applicant: Sumitomo Riko Company Limited, Aichi (JP)

(72) Inventors: Katsuhiko NAKANO, Aichi (JP); Masaki NASU, Aichi (JP); Takanori MURASE, Aichi (JP)

(73) Assignee: Sumitomo Riko Company Limited, Aichi (JP)

(21) Appl. No.: 16/278,744

(22) Filed: Feb. 19, 2019

Related U.S. Application Data
(63) Continuation of application No. PCT/JP2017/034129, filed on Sep. 21, 2017.

(30) Foreign Application Priority Data
Oct. 31, 2016 (JP) 2016-213852

(51) Int. Cl. H01L 41/047; H04R 19/02; B06B 1/02

(52) U.S. Cl. CPC H01L 41/0472; H01L 41/0477; B06B 1/0292; H04R 19/02

(57) ABSTRACT

Provided is an electrostatic transducer which is small in size and has a large electrostatic capacitance, while having a durable constituent part of a conduction path, said constituent part being connected to an electrode. This electrostatic transducer is provided with a plurality of first electrode sheets, a plurality of second electrode sheets and a plurality of dielectric sheets. Each one of the plurality of first electrode sheets is provided with a first counter electrode part and a first terminal electrode part. Each one of the plurality of second electrode sheets is provided with a second counter electrode part and a second terminal electrode part. Each one of the plurality of dielectric sheets is provided with a dielectric main body, a first extending part that is interposed between a plurality of first terminal electrode parts, and a second extending part that is interposed between a plurality of second terminal electrode parts.

### CROSS-REFERENCE TO RELATED APPLICATIONS

This application is a continuation application of International Application number PCT/JP2017/034129, filed on Sep. 21, 2017, which claims the priority benefit of Japan Patent Application No. 2016-213852, filed on Oct. 31, 2016. The entirety of each of the above-mentioned patent applications is hereby incorporated by reference herein and made a part of this specification.

### BACKGROUND

### Technical Field

The disclosure relates to an electrostatic transducer.

### Description of Related Art

An electrostatic transducer utilizes a change in electrostatic capacitance and is an actuator that generates vibration, sound, etc. or a sensor that detects vibration, sound, etc. Japanese Laid-open No. 2014-150600 describes an actuator in which a plurality of electrode covered bodies are alternately shifted layer by layer and laminated, which prevents creeping discharge between the electrodes. Besides, the electrode layer constituting each electrode covered body is connected to the power supply electrode.

Furthermore, Japanese Laid-open No. S63-10594 and Japanese Laid-open No. 2005-312230 describe devices that use piezoelectric elements. In the device described in Japanese Laid-open No. S63-10594, a large number of piezoelectric elements that have electrode thin films formed on the upper and lower surfaces are laminated with the upper and lower surfaces reversed alternately, and a side electrode is formed to commonly connect the electrode thin films. As to the device described in Japanese Laid-open No. 2005-312230, a configuration is described in which connection electrodes are disposed on both end surfaces of a roll body.

An electrostatic transducer that is small in size and has a large electrostatic capacitance is desirable. When a large number of electrode layers and dielectric layers are laminated to secure a large electrostatic capacitance, it is possible to form a transducer that has a small size and a large electrostatic capacitance by reducing the thickness of the electrode layer. However, for the electrostatic actuator described in Japanese Laid-open No. 2014-150600, it is difficult to make the electrode covered body having the electrode layer thinner, and when a large number of electrode covered bodies are laminated, the size of the whole actuator increases.

In addition, when the thickness of the electrode layer is reduced, how to configure the terminal to extract electricity from each electrode layer also becomes a problem. Particularly, because the electrode layer is thin, if the terminal is formed by extending the electrode layer, the durability of the electrode layer will be a problem. Particularly, since the dielectric of the electrostatic transducer is deformed, the portion of the electrode layer, which serves as the terminal, needs to be able to follow the deformation of the dielectric.

### SUMMARY

The disclosure provides an electrostatic transducer that is small in size and has a large electrostatic capacitance and can have a durable constituent part of a conduction path, which is connected to an electrode.

An electrostatic transducer according to the disclosure includes a plurality of first electrode sheets formed of an elastic deformable material in a sheet shape, a plurality of second electrode sheets formed of an elastic deformable material in a sheet shape, and a plurality of dielectric sheets formed of an elastic deformable material in a sheet shape.

Each of the first electrode sheets includes a first counter electrode part and a first terminal electrode part extending from the first counter electrode part. Each of the second electrode sheets includes a second counter electrode part facing the first counter electrode part, and a second terminal electrode part extending from the second counter electrode part.

Each of the dielectric sheets includes a dielectric main body interposed between the first counter electrode part and the second counter electrode part, a first extending part extending from the dielectric main body and interposed between the first terminal electrode parts, and a second extending part extending from the dielectric main body and interposed between the second terminal electrode parts.

That is, the first counter electrode part and the first terminal electrode part are the same first electrode sheet. Likewise, the second counter electrode part and the second terminal electrode part are the same second electrode sheet. The first electrode sheet and the second electrode sheet can be formed very thin. In other words, an electrostatic laminate composed of the first counter electrode part, the second counter electrode part, and the dielectric main body is small in size and has a large electrostatic capacitance.

Here, the first electrode sheet includes the first counter electrode part and the first terminal electrode part. For example, it is conceivable to put only the first terminal electrode part outside the electrostatic laminate as the configuration of the conduction path connected to the first counter electrode part. However, the first terminal electrode part is much thinner than the electrostatic laminate. Therefore, if only the first terminal electrode part is present outside the electrostatic laminate as the portion for extracting electricity from the first counter electrode part, it may receive a large deformation force near the boundary between the first terminal electrode part and the first counter electrode part.

According to the disclosure, instead of putting only the first terminal electrode part outside the electrostatic laminate, the first extending part, which is a part of the dielectric sheet, is present outside the electrostatic laminate, and the first terminal electrode part and the first extending part are laminated. Accordingly, the total thickness of the first terminal electrode part and the first extending part is smaller than that of the electrostatic laminate only by the thickness of the second electrode sheet. Therefore, it is possible to suppress generation of a large deformation force near the boundary between the first terminal electrode part and the first counter electrode part. As a result, the constituent part of the conduction path connected to the first counter electrode part can be highly durable. The same applies to the second terminal electrode part.

As described above, the dielectric sheet is disposed not only between the first counter electrode part and the second counter electrode part but also between the first terminal electrode parts and between the second terminal electrode parts. For the value of the electrostatic capacitance of the electrostatic transducer, the first extending part of the dielectric sheet that is present between the first terminal electrode parts, and the second extending part that is present between the second terminal electrode parts are unnecessary parts. However, by disposing the first extending part and the second extending part which are parts that do not contribute to the value of the electrostatic capacitance, as described above, the durability of the first terminal electrode part and the second terminal electrode part can be improved.

### BRIEF DESCRIPTION OF THE DRAWINGS

FIG. 1 is a cross-sectional view of the electrostatic transducer 1 of the first embodiment.

FIG. 2 is a cross-sectional view taken along the line II-II of FIG. 1.

FIG. 3 is an exploded perspective view of three electrostatic units 10a, 10b, and 10c.

FIG. 4 is an exploded perspective view of individual electrostatic units 10a, 10b, and 10c.

FIG. 5 is a diagram showing an electrical connection state of the electrostatic laminate 16.

FIG. 6 is a cross-sectional view of the electrostatic transducer 1 of the third embodiment.

FIG. 7 is a cross-sectional view taken along the line VII-VII of FIG. 6.

### DESCRIPTION OF THE EMBODIMENTS

### 1. First Embodiment

### (1-1. Outline of the Electrostatic Transducer 1)

An electrostatic transducer 1 utilizes a change in electrostatic capacitance and is an actuator that generates vibration, sound, etc. or a sensor that detects vibration, sound, etc. The electrostatic transducer 1, which serves as an actuator, generates vibration by applying a voltage to an electrode. The electrostatic transducer 1, which serves as a sensor, generates a voltage at an electrode when the sensor vibrates due to input of vibration or sound.

The electrostatic transducer 1, which serves as a vibration actuator, is, for example, a device for presenting tactile vibration to a human being, a device for generating vibration in an opposite phase to a structure for damping the structure, or the like. The electrostatic transducer 1, which serves as an actuator for generating sound, is a speaker for generating sound waves to be sensed by hearing of a human being, a sound masking for cancelling noise, or the like.

The vibration generated by the vibration actuator is vibration at a relatively low frequency, and the sound generated by the actuator for generating sound is vibration at a relatively high frequency. Since the electrostatic transducer 1, which serves as an actuator, in the present embodiment utilizes vibration of a spring mass system, it is suitable for a low frequency vibrator and a low frequency sound generator.

In the present embodiment, the electrostatic transducer 1 is, for example, a vibration actuator for presenting tactile vibration to a human being. For example, the electrostatic transducer 1 is applied to an actuator that is mounted on a portable terminal for vibrating the portable terminal. The electrostatic transducer 1, which serves as a sensor, has substantially the same configuration.

### (1-2. Configuration of the Electrostatic Transducer 1)

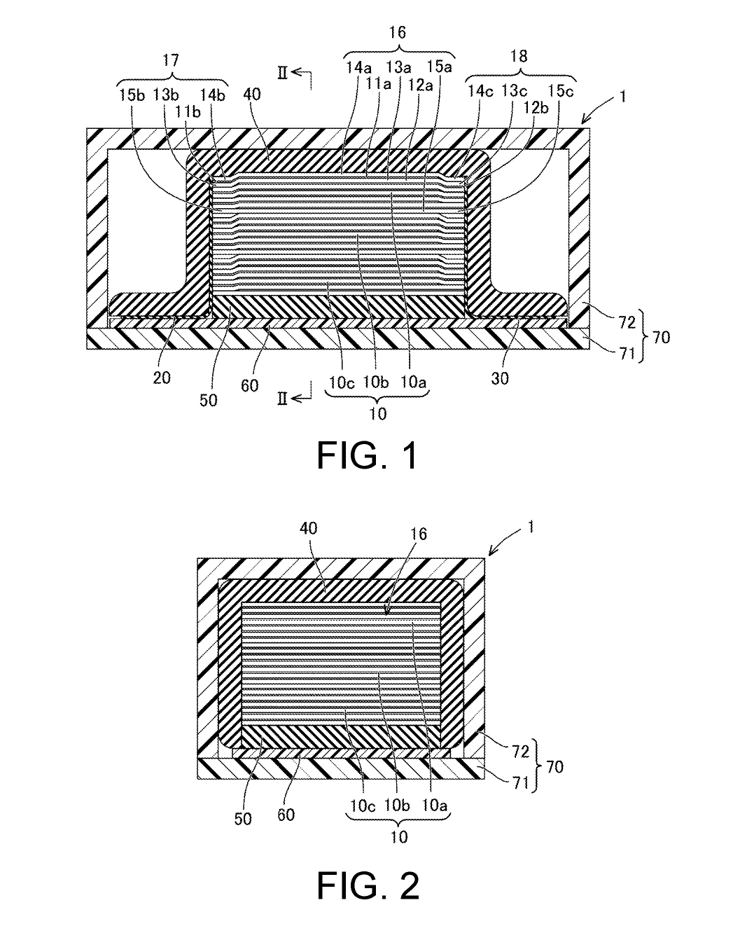

A configuration of the electrostatic transducer 1 will be described with reference to FIG. 1 to FIG. 4. Here, in FIG. 1 to FIG. 3, the thickness of each member is exaggerated for the sake of clarity. Therefore, in practice, the thickness of the electrostatic transducer 1 in the vertical direction of FIG. 1 is formed to be very small.

As shown in FIG. 1 and FIG. 2, the electrostatic transducer 1 includes an electrostatic unit 10 (10a, 10b, and 10c), a first conductive part 20, a second conductive part 30, a first elastic body 40, a second elastic body 50, a control substrate 60, and a cover 70.

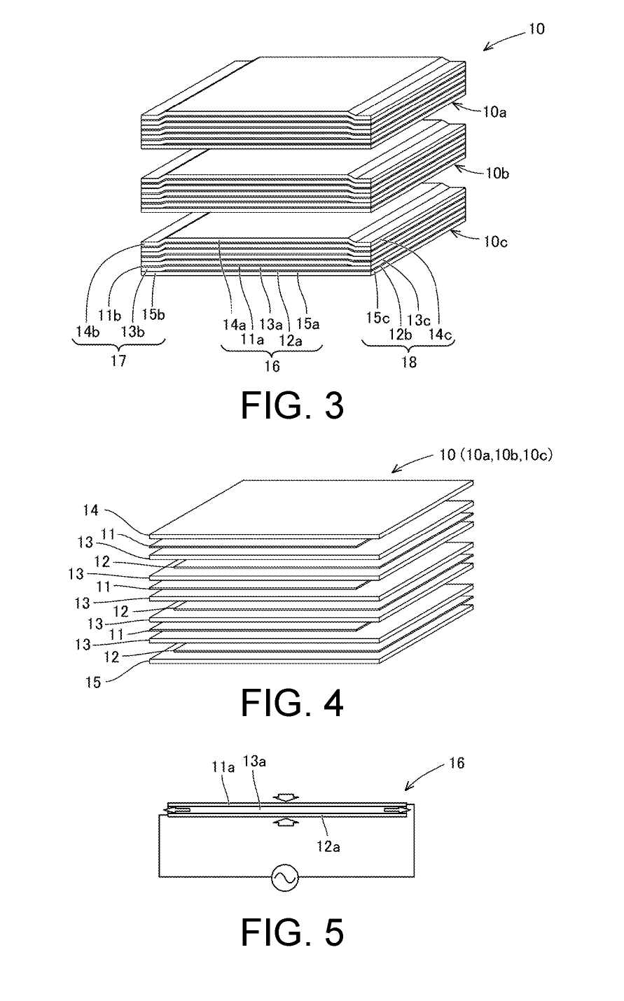

The electrostatic unit 10 includes a plurality of electrodes and a plurality of dielectrics that are laminated. The electrostatic transducer 1 may include one electrostatic unit 10 or include a plurality of electrostatic units 10. In the present embodiment, as shown in FIG. 3, the electrostatic transducer 1 includes three electrostatic units 10a, 10b, and 10c and is formed by laminating the three electrostatic units 10a, 10b, and 10c.

Each of the electrostatic units 10a, 10b, and 10c is formed in a substantially planar shape (corresponding to a flat shape). The outer shape of each of the electrostatic units 10a, 10b, and 10c is formed rectangular in the top view (when viewed from the surface normal direction) of FIG. 3. Each of the electrostatic units 10a, 10b, and 10c is formed of an elastomer.

As shown in FIG. 4, each of the electrostatic units 10a, 10b, and 10c includes a plurality of first electrode sheets 11, a plurality of second electrode sheets 12, a plurality of dielectric sheets 13, a front insulating sheet 14, and a back insulating sheet 15, and these are integral members. The electrostatic units 10a, 10b, and 10c are separate members.

First, the constituent members 11 to 15 of each of the electrostatic units 10a, 10b, and 10c will be described with reference to FIG. 4. The first electrode sheet 11 and the second electrode sheet 12 are formed of an elastic deformable material such as an elastomer in a sheet shape. The first electrode sheet 11 and the second electrode sheet 12 are formed in the same shape and formed of the same material. The first electrode sheet 11 and the second electrode sheet 12 are formed in the shape of a rectangular thin film.

The first electrode sheet 11 and the second electrode sheet 12 are formed by blending conductive fillers into the elastomer. Therefore, the first electrode sheet 11 and the second electrode sheet 12 have flexibility and stretchability. The elastomer constituting the first electrode sheet 11 and the second electrode sheet 12 may be silicone rubber, ethylene-propylene copolymer rubber, natural rubber, styrene-butadiene copolymer rubber, acrylonitrile-butadiene copolymer rubber, acrylic rubber, epichlorohydrin rubber, chlorosulfonated polyethylene, chlorinated polyethylene, urethane rubber, or the like, for example. In addition, the conductive fillers blended into the first electrode sheet 11 and the second electrode sheet 12 are particles having conductivity. For example, fine particles of a carbon material, metal, or the like may be used.

The dielectric sheet 13 is formed of an elastic deformable material such as an elastomer in a sheet shape. The dielectric sheet 13 is formed in the shape of a rectangular thin film. The width of the dielectric sheet 13 in the transverse direction is formed to be substantially equal to the widths of the first electrode sheet 11 and the second electrode sheet 12 in the transverse direction. In addition, the length of the dielectric sheet 13 in the longitudinal direction is formed to be larger than the lengths of the first electrode sheet 11 and the second electrode sheet 12 in the longitudinal direction. Moreover, the thickness of the dielectric sheet 13 is formed to be larger than the thicknesses of the first electrode sheet 11 and the second electrode sheet 12.

The dielectric sheet 13 is formed of an elastomer. Therefore, the dielectric sheet 13 has flexibility and stretchability. A material that functions as a dielectric of the electrostatic transducer 1 is applied as the dielectric sheet 13. Particularly, the dielectric sheet 13 stretches in the thickness direction and is stretchable in the flat plane direction along with its stretch in the thickness direction. The elastomer constituting the dielectric sheet 13 may be silicone rubber, acrylonitrile-butadiene copolymer rubber, acrylic rubber, epichlorohydrin rubber, chlorosulfonated polyethylene, chlorinated polyethylene, urethane rubber, or the like, for example.

An insulating material is applied as the front insulating sheet 14 and the back insulating sheet 15. In the present embodiment, the front insulating sheet 14 and the back insulating sheet 15 are formed of the same material in the same shape as the dielectric sheet 13. That is, the front insulating sheet 14 and the back insulating sheet 15 are formed of an elastomer and are rectangular.

As shown in FIG. 4, the first electrode sheet 11, the dielectric sheet 13, the second electrode sheet 12, the dielectric sheet 13, and the first electrode sheet 11 are laminated in this order. At this time, the first electrode sheet 11 and the second electrode sheet 12 are offset in the left-right direction (longitudinal direction) of FIG. 4. Specifically, a part of the first electrode sheet 11 and a part of the second electrode sheet 12 are disposed to face each other. Then, the remaining parts of the first electrode sheet 11 and the second electrode sheet 12, which do not face each other, are positioned on opposite sides with respect to the parts that face each other.

That is, in FIG. 4, in the center portion in the left-right direction, the first electrode sheet 11 and the second electrode sheet 12 face each other; in the left portion, the first electrode sheet 11 is present whereas the second electrode sheet 12 is not; and in the right portion, the second electrode sheet 12 is present whereas the first electrode sheet 11 is not.

The length of the dielectric sheet 13 in the longitudinal direction (width in the left-right direction of FIG. 4) is formed to cover all the range where the first electrode sheet 11 and the second electrode sheet 12 face each other, the range where only the first electrode sheet 11 is present, and the range where only the second electrode sheet 12 is present.

The front insulating sheet 14 covers the entire surface of one outermost layer (the uppermost layer in FIG. 4) of the first electrode sheets 11 and the second electrode sheets 12. The back insulating sheet 15 covers the entire surface of the other outermost layer (the lowermost layer in FIG. 4) of the first electrode sheets 11 and the second electrode sheets 12.

Next, each of the electrostatic units 10a, 10b, and 10c will be described with reference to FIG. 3. Each of the electrostatic units 10a, 10b, and 10c includes an electrostatic laminate 16 positioned in the center portion in the left-right direction of FIG.

3, a first terminal 17 positioned on the left side of FIG. 3, and a second terminal 18 positioned on the right side of FIG. 3. The first terminal 17 is a ground potential terminal of the electrostatic laminate 16 and the second terminal 18 is a positive electrode potential terminal of the electrostatic laminate 16. Here, the first terminal 17 and the second terminal 18 extend to opposite sides with respect to the electrostatic laminate 16.

Here, the first electrode sheet 11 includes a first counter electrode part 11a positioned in the center portion in the left-right direction, and a first terminal electrode part 11b extending from the first counter electrode part 11a. The second electrode sheet 12 includes a second counter electrode part 12a positioned in the center portion in the left-right direction, and a second terminal electrode part 12b extending from the second counter electrode part 12a. The first counter electrode part 11a and the second counter electrode part 12a face each other. A direction in which the first terminal electrode part 11b extends from the first counter electrode part 11a and a direction in which the second terminal electrode part 12b extends from the second counter electrode part 12a are opposite directions.

The dielectric sheet 13 includes a dielectric main body 13a, a first extending part 13b, and a second extending part 13c. The dielectric main body 13a is interposed between the first counter electrode part 11a and the second counter electrode part 12a. The first extending part 13b extends from the dielectric main body 13a and is interposed between the first terminal electrode parts 11b. The second extending part 13c extends from the dielectric main body 13a and is interposed between the second terminal electrode parts 12b.

In addition, the front insulating sheet 14 includes a front insulating main body 14a, a first front terminal insulating part 14b, and a second front terminal insulating part 14c. The front insulating main body 14a covers the first counter electrode part 11a positioned in one outermost layer (the upper side in FIG. 3). The first front terminal insulating part 14b covers the first terminal electrode part 11b positioned in one outermost layer. The second front terminal insulating part 14c covers the second terminal electrode part 12b positioned in one outermost layer.

The back insulating sheet 15 includes a back insulating main body 15a, a first back terminal insulating part 15b, and a second back terminal insulating part 15c. The back insulating main body 15a covers the first counter electrode part 11a positioned in the other outermost layer (the lower side in FIG. 3). The first back terminal insulating part 15b covers the first terminal electrode part 11b positioned in the other outermost layer. The second back terminal insulating part 15c covers the second terminal electrode part 12b positioned in the other outermost layer.

In other words, the electrostatic laminate 16 is formed in a planar shape by a plurality of first counter electrode parts 11 a, a plurality of second counter electrode parts 12a, a plurality of dielectric main bodies 13a, the front insulating main body 14a, and the back insulating main body 15a. The first terminal 17 is formed in a planar shape by a plurality of first terminal electrode parts 11b, a plurality of first extending parts 13b, the first front terminal insulating part 14b, and the first back terminal insulating part 15b. The first terminal 17 extends in the plane direction of the planar shape of the electrostatic laminate 16. The second terminal 18 is formed in a planar shape by a plurality of second terminal electrode parts 12b, a plurality of second extending parts 13c, the second front terminal insulating part 14c, and the second back terminal insulating part 15c. The second terminal 18 extends in the plane direction of the planar shape of the electrostatic laminate 16.

Here, the electrostatic laminate 16 includes all the constituent members, whereas the first terminal 17 does not include the second electrode sheet 12 and the second terminal 18 does not include the first electrode sheet 11. Therefore, the first terminal 17 and the second terminal 18 are thinner than the electrostatic laminate 16. However, the first electrode sheet 11 and the second electrode sheet 12 are very thin. Particularly, the first electrode sheet 11 and the second electrode sheet 12 are much thinner than the dielectric sheet 13. Therefore, the difference between the thickness of the electrostatic laminate 16 and the thickness of the first terminal 17 and the difference between the thickness of the electrostatic laminate 16 and the thickness of the second terminal 18 are not so large.

Therefore, the bending of the first electrode sheet 11 in the boundary portion between the first counter electrode part 11a and the first terminal electrode part 11b is small. Likewise, the bending in the boundary portion between the second counter electrode part 12a and the second terminal electrode part 12b is small.

Furthermore, since each of the electrostatic units 10a, 10b, and 10c is formed independently in the present embodiment, in each of the electrostatic units 10a, 10b, and 10c, the difference between the thickness of the electrostatic laminate 16 and the thickness of the first terminal 17 and the difference between the thickness of the electrostatic laminate 16 and the thickness of the second terminal 18 are not so large. Therefore, the bending of the first electrode sheet 11 in the boundary portion between the first counter electrode part 11a and the first terminal electrode part 11b is small. Further, the bending in the boundary portion between the second counter electrode part 12a and the second terminal electrode part 12b is small.

Description regarding the configuration of the electrostatic transducer 1 will be continued by reverting to FIG. 1 and FIG. 2. The first conductive part 20 is formed of an elastic deformable material (for example, an elastomer) in a sheet shape and bent in an L shape. Like the first electrode sheet 11, the first conductive part 20 is formed by blending conductive fillers into the elastomer. However, the first conductive part 20 is formed thicker than the first electrode sheet 11.

One side of the L shape of the first conductive part 20 is formed in a direction that intersects (is orthogonal to) the plane of the planar shape of the electrostatic laminate 16. Then, one side of the L shape of the first conductive part 20 is in contact with an end surface of the first terminal 17. Specifically, one side of the L shape of the first conductive part 20 is in contact with an end of the first terminal electrode part 11b and an end of the first extending part 13b. Therefore, the first conductive part 20 is electrically connected to the ends of the first terminal electrode parts 11b.

The other side of the L shape of the first conductive part 20 extends in a direction away from the electrostatic laminate 16 and is formed in parallel to the plane direction of the planar shape of the electrostatic laminate 16. The other side of the L shape of the first conductive part 20 is electrically connected to the control substrate 60 which will be described later.

Like the first conductive part 20, the second conductive part 30 is formed of an elastic deformable material (for example, an elastomer) in a sheet shape and bent in an L shape. The second conductive part 30 is formed by blending conductive fillers into the elastomer.

One side of the L shape of the second conductive part 30 is formed in a direction that intersects (is orthogonal to) the plane of the planar shape of the electrostatic laminate 16. Then, one side of the L shape of the second conductive part 30 is in contact with an end surface of the second terminal 18. Specifically, one side of the L shape of the second conductive part 30 is in contact with an end of the second terminal electrode part 12b and an end of the second extending part 13c. Therefore, the second conductive part 30 is electrically connected to the ends of the second terminal electrode parts 12b.

The other side of the L shape of the second conductive part 30 extends in a direction away from the electrostatic laminate 16 and is formed in parallel to the plane direction of the planar shape of the electrostatic laminate 16. The other side of the L shape of the second conductive part 30 is electrically connected to the control substrate 60 which will be described later.

The first elastic body 40 is disposed in contact with one surface of the planar shape of the electrostatic laminate 16. The second elastic body 50 is disposed in contact with the other surface of the planar shape of the electrostatic laminate 16. That is, the first elastic body 40 and the second elastic body 50 are respectively disposed on two end surfaces (the upper and lower surfaces in FIG. 1) that face away from each other in a direction orthogonal to the plane of the planar shape of the electrostatic laminate 16.

In addition, as shown in FIG. 2, the first elastic body 40 is disposed in contact with two end surfaces (the surfaces where the first terminal 17 and the second terminal 18 are not present (the left and right surfaces in FIG. 2)) that face away from each other in the plane direction of the planar shape of the electrostatic laminate 16. Furthermore, as shown in FIG. 1, the first elastic body 40 is disposed in contact with one surface (the upper surface in FIG. 1) of the planar shape of the first terminal 17 and one surface (the upper surface in FIG. 1) of the planar shape of the second terminal 18. The second elastic body 50 is disposed in contact with the other surface (the lower surface in FIG. 1) of the planar shape of the first terminal 17 and the other surface (the lower surface in FIG. 1) of the planar shape of the second terminal 18.

Moreover, the first elastic body 40 is disposed in contact with the entire outer surface of the L shape of the first conductive part 20 and the entire outer surface of the L shape of the second conductive part 30. The surface of the second elastic body 50 on the side opposite to the electrostatic laminate 16 is formed to be substantially flush with the other surfaces of the L shapes of the first conductive part 20 and the second conductive part 30.

For the first elastic body 40 and the second elastic body 50, materials having small elastic moduli E₍₄₀₎ and E₍₅₀₎ and small loss factors tanδ₍₄₀₎ and tanδ₍₅₀₎ are used.

In other words, materials that are soft and have low attenuation characteristics are suitable for the first elastic body 40 and the second elastic body 50. Particularly, the first elastic body 40 and the second elastic body 50 have elastic moduli E₍₄₀₎ and E₍₅₀₎ that are smaller than the elastic modulus E1₍₁₆₎ in the lamination direction (the direction orthogonal to the plane of the planar shape) of the electrostatic laminate 16. In addition, the elastic modulus E₍₄₀₎ of the first elastic body 40 is smaller than the elastic modulus E2₍₁₆₎ in the plane direction of the electrostatic laminate 16.

Specifically, the ratio of the elastic modulus E₍₄₀₎ of the first elastic body 40 to the elastic modulus E1₍₁₆₎ in the lamination direction of the electrostatic laminate 16 is 15% or less. Further, the ratio of the elastic modulus E₍₅₀₎ of the second elastic body 50 to the elastic modulus E1₍₁₆₎ in the lamination direction of the electrostatic laminate 16 is 15% or less. These ratios are preferably 10% or less. Likewise, the ratio of the elastic modulus E₍₄₀₎ of the first elastic body 40 to the elastic modulus E2₍₁₆₎ in the plane direction of the electrostatic laminate 16 is 15% or less. Further, the ratio of the elastic modulus E₍₅₀₎ of the second elastic body 50 to the elastic modulus E2₍₁₆₎ in the plane direction of the electrostatic laminate 16 is 15% or less. These ratios are preferably 10% or less.

Besides, the first elastic body 40 and the second elastic body 50 have loss factors tanδ₍₄₀₎ and tanδ₍₅₀₎ equal to or smaller than the loss factor tanδ₍₁₆₎ of the electrostatic laminate 16 under a predetermined condition. The predetermined condition means an environment of use where the temperature is set to −10° C. to 50° C. and the vibration frequency is set to 300 Hz or less.

As a material that satisfies the above, silicone rubber, for example, is suitable for the first elastic body 40 and the second elastic body 50. Urethane rubber, for example, has better attenuation characteristics than silicone rubber. Therefore, urethane rubber is less suitable for the first elastic body 40 and the second elastic body 50 than silicone rubber. However, it is also possible to use urethane rubber for the first elastic body 40 and the second elastic body 50 depending on the desired characteristics.

The control substrate 60 is disposed parallel to the electrostatic laminate 16 and is disposed in contact with the surface of the second elastic body 50 on the side opposite to the electrostatic laminate 16. Furthermore, the control substrate 60 is in contact with the other surfaces of the L shapes of the first conductive part 20 and the second conductive part 30.

The cover 70 surrounds the electrostatic units 10, the first conductive part 20, the second conductive part 30, the first elastic body 40, the second elastic body 50, and the control substrate 60. Various materials such as metal and resin are suitable for the cover 70. The cover 70 includes a planar first cover 71 for fixing the control substrate 60, and a second cover 72 attached to the first cover 71.

The first cover 71 and the second cover 72 hold the electrostatic laminate 16, the first elastic body 40, and the second elastic body 50 in a state of compressing them in the lamination direction of the electrostatic laminate 16. In this state, according to the relationship between the elastic moduli E of the members, the first elastic body 40 and the second elastic body 50 are compressed to a greater extent than the electrostatic laminate 16 in the lamination direction of the electrostatic laminate 16.

Furthermore, the first cover 71 holds the electrostatic laminate 16 and the first elastic body 40 in a state of compressing them in the plane direction of the electrostatic laminate 16. In this state, according to the relationship between the elastic moduli E of the members, the first elastic body 40 is compressed to a greater extent than the electrostatic laminate 16 in the plane direction of the electrostatic laminate 16.

### (1-3. Electrical Connection State of the Electrostatic Laminate 16)

An electrical connection state of the electrostatic laminate 16 will be described with reference to FIG. 5. Here, the vertical direction of FIG. 5 and the vertical direction of FIG. 1 coincide with each other. However, FIG. 5 shows one electrostatic cell that constitutes the electrostatic laminate 16. The electrostatic cell is one first counter electrode part 11a, one second counter electrode part 12a, and one dielectric main body 13a.

As shown in FIG. 5, the first counter electrode part 11 a and the second counter electrode part 12a are disposed to face each other at a distance in the lamination direction of the electrostatic laminate 16. The other terminal that supplies a periodic voltage is electrically connected to the first counter electrode part 11a by a driving circuit in the control substrate 60. One terminal that supplies a periodic voltage is electrically connected to the second counter electrode part 12a. In the present embodiment, the first counter electrode part 11a is connected to the ground potential. The second counter electrode part 12a is connected to the output terminal of the control substrate 60.

### (1-4. Operation of the Electrostatic Transducer 1)

An operation of the electrostatic transducer 1 will be described. A periodic voltage is applied to the first counter electrode part 11a and the second counter electrode part 12a via the first terminal electrode part 11b and the second terminal electrode part 12b. Here, the periodic voltage may be an alternating voltage (a periodic voltage including positive and negative) or a periodic voltage offset to a positive value.

As the electric charge accumulated in the first counter electrode part 11a and the second counter electrode part 12a increases, the dielectric main body 13a is compressed and deformed. That is, as shown in FIG. 5, the thickness of the electrostatic laminate 16 decreases and the size (width and depth) in the plane direction of the electrostatic laminate 16 increases. Conversely, as the electric charge accumulated in the first counter electrode part 11a and the second counter electrode part 12a decreases, the dielectric main body 13a returns to the original thickness. That is, the thickness of the electrostatic laminate 16 increases and the size in the plane direction of the electrostatic laminate 16 decreases. In this way, the electrostatic laminate 16 stretches in the lamination direction and stretches in the plane direction.

When the electrostatic laminate 16 stretches, the electrostatic transducer 1 operates as follows. The electrostatic transducer 1 sets the state where the first elastic body 40 and the second elastic body 50 are compressed, as shown in FIG. 1, as the initial state. Therefore, when the thickness of the electrostatic laminate 16 decreases due to the increase in electric charge, the first elastic body 40 and the second elastic body 50 are deformed so that the compression amount is smaller than that in the initial state. Conversely, when the thickness of the electrostatic laminate 16 increases due to the decrease in electric charge, the first elastic body 40 and the second elastic body 50 operate so as to return to the initial state. That is, the first elastic body 40 and the second elastic body 50 are deformed so that the compression amount is larger than in the case where the electric charge increases.

Since the applied voltage changes periodically, the above operation is repeated. Then, the state where the center of the electrostatic laminate 16 is recessed toward the side of the second elastic body 50 and the state where the center of the electrostatic laminate 16 protrudes toward the side of the second elastic body 50 are repeated. Since the electrostatic laminate 16 is restricted by the cover 70 via the first elastic body 40 and the second elastic body 50, the above operation is performed.

Along with the above deformation of the electrostatic laminate 16, the displacement in the lamination direction (d33 direction: direction the same as the electric field) of the electrostatic laminate 16 is transmitted to the cover 70 via the first elastic body 40. In addition, the elastic deformation force of the first elastic body 40 is changed by the stretch of the electrostatic laminate 16. The change in the elastic deformation force of the first elastic body 40 is transmitted to the cover 70. Accordingly, as the initial state, since the first elastic body 40 and the second elastic body 50 are compressed, vibration in the lamination direction (d33 direction) of the electrostatic laminate 16 can be efficiently transferred to the cover 70. That is, even though the electrostatic laminate 16 alone generates small vibration, the cover 70 can have tactile vibration.

Further, along with the above deformation of the electrostatic laminate 16, the displacement in the plane direction (d31 direction: direction orthogonal to the electric field) of the electrostatic laminate 16 is transmitted to the cover 70 via the first elastic body 40. As a result, the vibration in the plane direction (d31 direction) of the electrostatic laminate 16 is transferred to the cover 70. Here, the vibration in the plane direction (d31 direction) of the electrostatic laminate 16 is smaller than the vibration in the lamination direction (d33 direction). However, the vibration in the plane direction (d31 direction) is added to the vibration in the lamination direction (d33 direction) of the electrostatic laminate 16, by which the whole cover 70 can have large tactile vibration.

Here, assuming that the loss factors tanδ₍₄₀₎ and tanδ₍₅₀₎ of the first elastic body 40 and the second elastic body 50 are very large, the vibration may be absorbed by the first elastic body 40 and the second elastic body 50 even if the electrostatic laminate 16 stretches. In such a case, even if the electrostatic laminate 16 stretches, the vibration is not transmitted to the cover 70.

However, in the present embodiment, the first elastic body 40 and the second elastic body 50 use materials that have small loss factors tanδ₍₄₀₎ and tanδ₍₅₀₎. Therefore, the vibration generated by the stretch of the electrostatic laminate 16 is hardly absorbed by the first elastic body 40 and the second elastic body 50 and is transmitted to the cover 70.

Furthermore, the elastic moduli E₍₄₀₎ and E₍₅₀₎ of the first elastic body 40 and the second elastic body 50 are smaller than the elastic modulus E1₍₁₆₎ in the lamination direction of the electrostatic laminate 16. Therefore, in the initial state where no voltage is applied to the first counter electrode part 11a and the second counter electrode part 12a, the electrostatic laminate 16 is barely compressed. Accordingly, even if the cover 70 presses the electrostatic laminate 16 in the lamination direction, it does not affect the stretch of the electrostatic laminate 16 in the lamination direction. In other words, the electrostatic laminate 16 can stretch reliably.

In addition, the elastic modulus E₍₄₀₎ of the first elastic body 40 is smaller than the elastic modulus E2₍₁₆₎ in the plane direction of the electrostatic laminate 16. Therefore, in the initial state where no voltage is applied to the first counter electrode part 11a and the second counter electrode part 12a, the electrostatic laminate 16 is barely compressed. Accordingly, even if the cover 70 presses the electrostatic laminate 16 in the plane direction, it does not affect the stretch of the electrostatic laminate 16 in the plane direction. In other words, the electrostatic laminate 16 can stretch reliably.

In the embodiment described above, the first elastic body 40 may be disposed only on the end surfaces in the direction orthogonal to the plane of the electrostatic laminate 16. In such a case, the first elastic body 40 is not disposed on the end surfaces in the plane direction of the electrostatic laminate 16. Therefore, the electrostatic transducer 1 does not transfer vibration in the plane direction (d31 direction) of the electrostatic laminate 16 to the cover 70.

### 2. Second Embodiment

In the second embodiment, the outermost layer of the electrostatic laminate 16 is formed with an elastic modulus in the lamination direction larger than those of the other layers. The outermost layer of the electrostatic laminate 16 is the uppermost layer of the electrostatic unit 10a in FIG. 3 and the lowermost layer of the electrostatic unit 10c in FIG. 3. For example, by applying UV irradiation to surface-modify the uppermost layer of the electrostatic unit 10a, a nano-order cured layer is formed. Likewise, by applying

UV irradiation to surface-modify the lowermost layer of the electrostatic unit 10c, a nano-order cured layer is formed. A sheet having a desired elastic modulus may be disposed instead of applying UV irradiation. Therefore, when the vibration in the lamination direction of the electrostatic laminate 16 is transmitted to the cover 70, the transmission sensitivity of the vibration is improved.

### 3. Third Embodiment

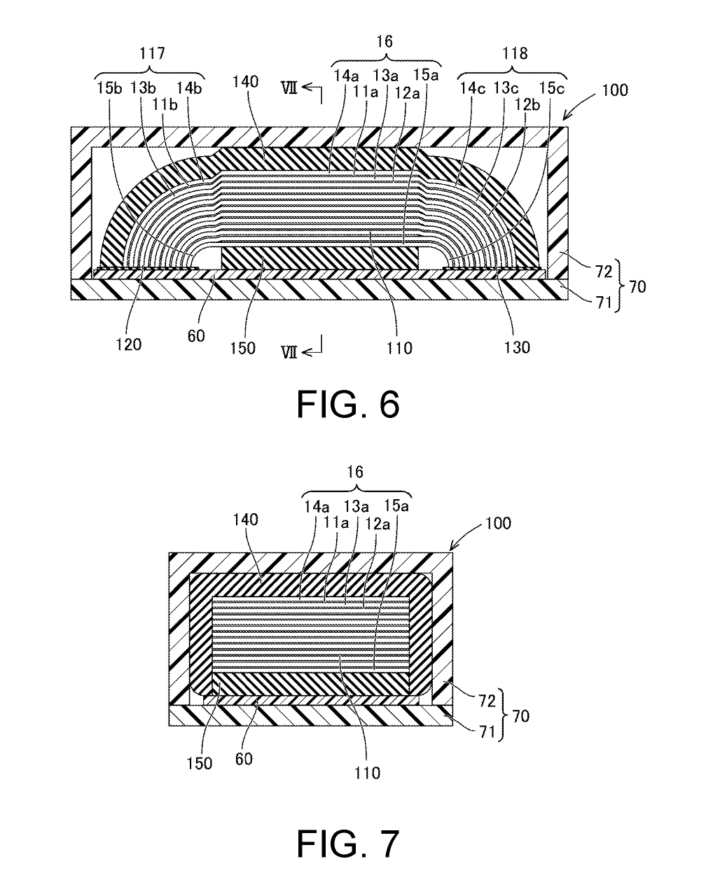

An electrostatic transducer 100 of the third embodiment will be described with reference to FIG. 6 and FIG. 7. In the electrostatic transducer 100, components the same as those of the electrostatic transducer 1 of the first embodiment are denoted by the same reference numerals, and description thereof is omitted.

The electrostatic transducer 100 includes an electrostatic unit 110, a first conductive part 120, a second conductive part 130, a first elastic body 140, a second elastic body 150, a control substrate 60, and a cover 70.

The electrostatic unit 110 includes an electrostatic laminate 16, a first terminal 117, and a second terminal 118. The electrostatic laminate 16 is formed in a planar shape. The electrostatic laminate 16 is formed by a first counter electrode part 11a, a second counter electrode part 12a, and a dielectric main body 13a. In other words, the first counter electrode part 11a, the second counter electrode part 12a, and the dielectric main body 13a are formed in a planar shape.

The first terminal 117 is bent in a curved shape from a plane direction of the planar shape of the electrostatic laminate 16. The first terminal 117 is formed in an arc shape of about 90 degrees. Here, the first terminal 117 is formed by a first terminal electrode part 11b and a first extending part 13b. In other words, the first terminal electrode part 11b and the first extending part 13b are bent in a curved shape.

The second terminal 118 is bent in a curved shape from the plane direction of the planar shape of the electrostatic laminate 16. The second terminal 118 is formed in an arc shape of about 90 degrees. Here, the second terminal 118 is formed by a second terminal electrode part 12b and a second extending part 13c. In other words, the second terminal electrode part 12b and the second extending part 13c are bent in a curved shape.

The first conductive part 120 and the second conductive part 130 are formed in a planar sheet shape. The first conductive part 120 and the second conductive part 130 are in contact with the ends of the first terminal 117 and the second terminal 118 respectively. In addition, the first conductive part 120 and the second conductive part 130 are formed in parallel to the plane direction of the planar shape of the electrostatic laminate 16. The first conductive part 120 and the second conductive part 130 are electrically connected to the control substrate 60.

As shown in FIG. 6 and FIG. 7, the first elastic body 140 is disposed in contact with one surface (the upper surface in FIG. 6 and FIG. 7) of the planar shape of the electrostatic laminate 16. Further, as shown in FIG. 7, the first elastic body 140 is disposed in contact with two end surfaces (the left and right surfaces in FIG. 7) that face away from each other in the plane direction of the planar shape of the electrostatic laminate 16. Also, as shown in FIG. 6, the first elastic body 140 is disposed in contact with the curved convex surface of the first terminal 117 and the curved convex surface of the second terminal 118. Although not shown, the first elastic body 140 may be disposed in contact with the side surfaces (the front and rear surfaces in FIG. 6) of the first terminal 117 and the side surfaces (the front and rear surfaces in FIG. 6) of the second terminal 118.

In addition, as shown in FIG. 6 and FIG. 7, the second elastic body 150 is disposed in contact with the other surface (the lower surface in FIG. 6 and FIG. 7) of the planar shape of the electrostatic laminate 16. In FIG. 6, the second elastic body 150 is not in contact with the curved concave surface of the first terminal 117 and the curved concave surface of the second terminal 118, but it may be disposed in contact with the curved concave surfaces.

### <4. Effect>

The electrostatic transducer 1, 100 of the first, second, and third embodiments includes a plurality of first electrode sheets 11 formed of an elastic deformable material in a sheet shape, a plurality of second electrode sheets 12 formed of an elastic deformable material in a sheet shape, and a plurality of dielectric sheets 13 formed of an elastic deformable material in a sheet shape.

Each of the first electrode sheets 11 includes the first counter electrode part 11a and the first terminal electrode part 11b extending from the first counter electrode part 11a. Each of the second electrode sheets 12 includes the second counter electrode part 12a facing the first counter electrode part 11a, and the second terminal electrode part 12b extending from the second counter electrode part 12a.

Each of the dielectric sheets 13 includes the dielectric main body 13a interposed between the first counter electrode part 11a and the second counter electrode part 12a, the first extending part 13b extending from the dielectric main body 13a and interposed between the first terminal electrode parts 11b, and the second extending part 13c extending from the dielectric main body 13a and interposed between the second terminal electrode parts 12b.

In other words, the first counter electrode part 11 a and the first terminal electrode part 11b are the same first electrode sheet 11. Likewise, the second counter electrode part 12a and the second terminal electrode part 12b are the same second electrode sheet 12. The first electrode sheet 11 and the second electrode sheet 12 can be formed very thin. That is, the electrostatic laminate 16 composed of the first counter electrode part 11a, the second counter electrode part 12a, and the dielectric main body 13a is small in size and has a large electrostatic capacitance.

Here, the first electrode sheet 11 includes the first counter electrode part 11a and the first terminal electrode part 11b. For example, it is conceivable to put only the first terminal electrode part 11b outside the electrostatic laminate 16 as the configuration of the conduction path connected to the first counter electrode part 11a. However, the first terminal electrode part 11b is much thinner than the electrostatic laminate 16. Therefore, if only the first terminal electrode part 11b is present outside the electrostatic laminate 16 as the portion for extracting electricity from the first counter electrode part 11a, it may receive a large deformation force near the boundary between the first terminal electrode part 11b and the first counter electrode part 11a.

However, according to the first, second, and third embodiments, instead of putting only the first terminal electrode part 11b outside the electrostatic laminate 16, the first extending part 13b, which is a part of the dielectric sheet 13, is present outside the electrostatic laminate 16, and the first terminal electrode part 11b and the first extending part 13b are laminated. Accordingly, the total thickness of the first terminal electrode part 11b and the first extending part 13b is smaller than that of the electrostatic laminate 16 only by the thickness of the second electrode sheet 12. Therefore, it is possible to suppress generation of a large deformation force near the boundary between the first terminal electrode part 11b and the first counter electrode part 11a. As a result, the constituent part of the conduction path connected to the first counter electrode part 11a can be highly durable. The same applies to the second terminal electrode part 12b.

As described above, the dielectric sheet 13 is disposed not only between the first counter electrode part 11a and the second counter electrode part 12a but also between the first terminal electrode parts 11b and between the second terminal electrode parts 12b. For the value of the electrostatic capacitance of the electrostatic transducer 1, the first extending part 13b of the dielectric sheet 13 that is present between the first terminal electrode parts 11b, and the second extending part 13c that is present between the second terminal electrode parts 12b are unnecessary parts. However, by disposing the first extending part 13b and the second extending part 13c which are parts that do not contribute to the value of the electrostatic capacitance, as described above, the durability of the first terminal electrode part 11b and the second terminal electrode part 12b can be improved.

Furthermore, in the first, second, and third embodiments, the direction in which the first terminal electrode part 11b extends from the first counter electrode part 11a, and the direction in which the second terminal electrode part 12b extends from the second counter electrode part 12a are opposite directions. That is, the first terminal 17 formed by the first terminal electrode part 11b and the first extending part 13b, and the second terminal 18 formed by the second terminal electrode part 12b and the second extending part 13c face away from each other. Therefore, among the peripheral surfaces (the peripheral surfaces around the surface normal) of the electrostatic laminate 16, the surfaces (the left and right surfaces in FIG. 2 and FIG. 7) adjacent to the first terminal 17 and the second terminal 18 face away from each other. Accordingly, it is possible to convert deformation of the electrostatic laminate 16 and electricity on the adjacent surfaces.

In addition, in the first, second, and third embodiments, the electrostatic transducer 1 includes the first conductive part 20 and the second conductive part 30. The first conductive part 20 is formed of an elastic deformable material, and is in contact with the end of the first terminal electrode part 11b and the end of the first extending part 13b and is electrically connected to the ends of the first terminal electrode parts 11b.

The second conductive part 30 is formed of an elastic deformable material, and is in contact with the end of the second terminal electrode part 12b and the end of the second extending part 13c and is electrically connected to the ends of the second terminal electrode parts 12b.

With the first conductive part 20, it is possible to easily form the conduction path between the first terminal electrode parts 11b. Likewise, with the second conductive part 30, it is possible to easily form the conduction path between the second terminal electrode parts 12b. In addition, since the first conductive part 20 and the second conductive part 30 are elastic and deformable, they can follow the deformation of the first terminal 17 and the second terminal 18. Therefore, even if the first terminal 17 and the second terminal 18 are deformed, the conduction path can be easily formed between the first terminal electrode part 11b and the second terminal electrode part 12b.

Moreover, in the first and second embodiments, the electrostatic laminate 16 composed of the first counter electrode part 11a, the second counter electrode part 12a, and the dielectric main body 13a is formed in a planar shape. Then, the first terminal electrode part 11b, the second terminal electrode part 12b, the first extending part 13b, and the second extending part 13c extend in the plane direction of the planar shape of the electrostatic laminate 16. Therefore, it is possible to suppress generation of a large deformation force near the boundary between the first terminal electrode part 11b and the first counter electrode part 11a. As a result, the constituent part for extracting electricity from the first counter electrode part 11a can be highly durable. The same applies to the second terminal electrode part 12b.

Further, in the first and second embodiments, the electrostatic laminate 16 composed of the first counter electrode part 11a, the second counter electrode part 12a, and the dielectric main body 13a is formed in a planar shape. Then, the first terminal electrode part 11b, the second terminal electrode part 12b, the first extending part 13b, and the second extending part 13c extend in the plane direction of the planar shape of the electrostatic laminate 16. Furthermore, the first conductive part 20 and the second conductive part 30 are formed in the direction that intersects the plane of the planar shape. Therefore, it is possible to suppress generation of a large deformation force near the boundary between the first terminal electrode part 11b and the first counter electrode part 11a, and the conduction path of the first conductive part 20 can also be set freely. The same applies to the second terminal electrode part 12b.

Particularly, the electrostatic transducer 1 includes a plurality of electrostatic units 10a, 10b, and 10c that are laminated. Each of the electrostatic units 10a, 10b, and 10c is formed by integrally forming the first electrode sheet 11, the second electrode sheet 12, and the dielectric sheet 13. Then, the first conductive part 20 is electrically connected to the first terminal electrode parts 11b in the electrostatic units 10a, 10b, and 10c. The second conductive part 30 is electrically connected to the second terminal electrode parts 12b in the electrostatic units 10a, 10b, and 10c.

Therefore, it is possible to laminate a large number of first electrode sheets 11, a large number of second electrode sheets 12, and a large number of dielectric sheets 13. At this time, in each of the electrostatic units 10a, 10b, and 10c, it is possible to suppress generation of a large deformation force near the boundary between the first terminal electrode part 11b and the first counter electrode part 11a. The same applies to the second terminal electrode part 12b.

Furthermore, in the third embodiment, the electrostatic laminate 16 composed of the first counter electrode part 11a, the second counter electrode part 12a, and the dielectric main body 13a is formed in a planar shape. The first terminal electrode part 11b and the first extending part 13b are bent in a curved shape from the plane direction of the planar shape of the electrostatic laminate 16. Moreover, the second terminal electrode part 12b and the second extending part 13c are bent in a curved shape from the plane direction of the planar shape.

Thus, in the case where the direction of the end surface of the first terminal 17 is changed, by bending the first terminal 17 in a curved shape, it is possible to suppress generation of a large deformation force near the boundary between the first terminal electrode part 11b and the first counter electrode part 11a. The same applies to the second terminal 18.

Particularly, the electrostatic laminate 16 composed of the first counter electrode part 11a, the second counter electrode part 12a, and the dielectric main body 13a is formed in a planar shape. The first terminal electrode part 11b and the first extending part 13b are bent in a curved shape from the plane direction of the planar shape of the electrostatic laminate 16. In addition, the second terminal electrode part 12b and the second extending part 13c are bent in a curved shape from the plane direction of the planar shape of the electrostatic laminate 16. Then, the first conductive part 20 and the second conductive part 30 are formed in parallel to the plane direction of the planar shape of the electrostatic laminate 16. Therefore, it is easy to form the electrostatic transducer 1 in a flat shape as a whole.

Also, in the first, second, and third embodiments, the electrostatic transducer 1 further includes the insulating sheets 14 and 15 covering the entire surfaces of the outermost layers of the first electrode sheets 11 and the second electrode sheets 12. Thus, the insulating coating of the electrostatic laminate 16, the insulating coating of the first terminal 17, and the insulating coating of the second terminal 18 can be made very simply.

Besides, in the first, second, and third embodiments, the electrostatic laminate 16 composed of the first counter electrode part 11a, the second counter electrode part 12a, and the dielectric main body 13a is formed in a planar shape. Then, the electrostatic transducer 1 includes the elastic bodies 40 and 50 which are respectively disposed on two end surfaces (the upper and lower surfaces in FIG. 1) that face away from each other in the direction (surface normal direction) orthogonal to the plane of the planar shape of the electrostatic laminate 16. In addition, the electrostatic transducer 1 includes the cover 70 that presses the electrostatic laminate 16 in the lamination direction and holds the elastic bodies 40 and 50 in a state of compressing them to a greater extent than the electrostatic laminate 16. Thus, even though the electrostatic laminate 16 alone generates small vibration, the cover 70 can have large vibration in the lamination direction of the electrostatic laminate 16.

In addition, in the first, second, and third embodiments, the elastic body 40 is disposed on two end surfaces (the upper and lower surfaces in FIG. 1) that face away from each other in the direction (surface normal direction) orthogonal to the plane of the planar shape of the electrostatic laminate 16, and on two end surfaces (the left and right surfaces in FIG. 1) that face away from each other in the plane direction of the planar shape of the electrostatic laminate 16. Further, the cover 70 presses in the plane direction of the electrostatic laminate 16 and holds the elastic body 40 in a state of compressing it to a greater extent than the electrostatic laminate 16. Thus, vibration in the plane direction of the electrostatic laminate 16 can be utilized. Then, even though the electrostatic laminate 16 alone generates small vibration, the cover 70 can have large vibration in both the lamination direction and the plane direction.

The elastic moduli E₍₄₀₎ and E₍₅₀₎ of the elastic bodies 40 and 50 are smaller than the elastic moduli E1₍₁₆₎ and E2₍₁₆₎ of the electrostatic laminate 16. That is, in the initial state, in the state where the electrostatic laminate 16 and the elastic bodies 40 and 50 are pressed by the cover 70, the compression amount of the electrostatic laminate 16 is small. Therefore, even if the electrostatic laminate 16 is pressed by the cover 70, it does not significantly affect the stretch of the electrostatic laminate 16.

Then, when a voltage is applied to the first counter electrode part 11 a and the second counter electrode part 12a of the electrostatic laminate 16, the electrostatic laminate 16 stretches in the lamination direction and the plane direction. The displacement of the plane of the electrostatic laminate 16 caused by the stretch of the electrostatic laminate 16 is transmitted to the cover 70 via the elastic bodies 40 and 50. In addition, the elastic deformation force of the elastic bodies 40 and 50 changes due to the stretch of the electrostatic laminate 16, and the change of the elastic deformation force of the elastic bodies 40 and 50 is transmitted to the cover 70. Accordingly, as the initial state, since the elastic bodies 40 and 50 are compressed, the vibration can be efficiently transferred to the cover 70. That is, even though the electrostatic laminate 16 alone generates small vibration, the cover 70 can have tactile vibration.

Furthermore, the elastic bodies 40 and 50 use materials having small loss factors tanδ₍₄₀₎ and tanδ₍₅₀₎. Thus, the elastic bodies 40 and 50 can transmit the vibration generated by the stretch of the electrostatic laminate 16 to the cover 70 without absorbing it. Particularly, the above operation can be realized reliably by using silicone rubber to form the elastic bodies 40 and 50.

In addition, the loss factors tanδ₍₄₀₎ and tanδ₍₅₀₎ of the elastic bodies 40 and 50 are set to be equal to or smaller than the loss factor tanδ₍₁₆₎ of the electrostatic laminate 16 under the predetermined condition. As described above, the predetermined condition refers to an environment of use where the temperature is set to −10° C. to 50° C. and the vibration frequency is set to 300 Hz or less. Thus, the elastic bodies 40 and 50 can reliably transmit the vibration generated by the stretch of the electrostatic laminate 16 to the cover 70 without absorbing it.

Also, in the second embodiment, the outermost layer of the electrostatic laminate 16 composed of the first counter electrode part 11a, the second counter electrode part 12a, and the dielectric main body 13a is formed with an elastic modulus in the lamination direction larger than those of the other layers. Thus, the vibration generated by the stretch of the electrostatic laminate 16 is more efficiently transmitted to the cover 70.

Particularly, the outermost layer of the electrostatic laminate 16 is preferably a layer surface-modified by UV irradiation. Therefore, the outermost layer can be very thin and have a nano-order thickness. Thus, the transmission efficiency of the vibration generated by the stretch can be improved without hindering the stretch itself of the electrostatic laminate 16.

What is claimed is:

1. An electrostatic transducer, comprising:
a plurality of first electrode sheets formed of an elastic deformable material in a sheet shape;
a plurality of second electrode sheets formed of an elastic deformable material in a sheet shape; and
a plurality of dielectric sheets formed of an elastic deformable material in a sheet shape,
wherein each of the first electrode sheets comprises a first counter electrode part and a first terminal electrode part extending from the first counter electrode part,
each of the second electrode sheets comprises a second counter electrode part facing the first counter electrode part, and a second terminal electrode part extending from the second counter electrode part, and
each of the dielectric sheets comprises:
a dielectric main body interposed between the first counter electrode part and the second counter electrode part;
a first extending part extending from the dielectric main body and interposed between the first terminal electrode parts; and
a second extending part extending from the dielectric main body and interposed between the second terminal electrode parts.

2. The electrostatic transducer according to claim 1, wherein a direction in which the first terminal electrode part extends from the first counter electrode part, and a direction in which the second terminal electrode part extends from the second counter electrode part are opposite directions.

3. The electrostatic transducer according to claim 1, further comprising:
a first conductive part formed of an elastic deformable material, and the first conductive part being in contact with an end of the first terminal electrode part and an end of the first extending part and being electrically connected to the ends of the first terminal electrode parts; and
a second conductive part formed of an elastic deformable material, and the second conductive part being in contact with an end of the second terminal electrode part and an end of the second extending part and being electrically connected to the ends of the second terminal electrode parts.

4. The electrostatic transducer according to claim 1, wherein the first counter electrode part, the second counter electrode part, and the dielectric main body constitute an electrostatic laminate, and the electrostatic laminate is formed in a planar shape, and
the first terminal electrode part, the second terminal electrode part, the first extending part, and the second extending part extend in a plane direction of the planar shape.

5. The electrostatic transducer according to claim 3, wherein the first counter electrode part, the second counter electrode part, and the dielectric main body constitute an electrostatic laminate, and the electrostatic laminate is formed in a planar shape,
the first terminal electrode part, the second terminal electrode part, the first extending part, and the second extending part extend in a plane direction of the planar shape, and
the first conductive part and the second conductive part are formed in a direction that intersects a plane of the planar shape.

6. The electrostatic transducer according to claim 5, wherein the first electrode sheet, the second electrode sheet, and the dielectric sheet integrally form a member, and the member is an electrostatic unit,
the electrostatic transducer comprises a plurality of the electrostatic units that are laminated,
the first conductive part is electrically connected to the first terminal electrode parts in the electrostatic units, and
the second conductive part is electrically connected to the second terminal electrode parts in the electrostatic units.

7. The electrostatic transducer according to claim 1, wherein the first counter electrode part, the second counter electrode part, and the dielectric main body constitute an electrostatic laminate, and the electrostatic laminate is formed in a planar shape,
the first terminal electrode part and the first extending part are bent in a curved shape from a plane direction of the planar shape, and
the second terminal electrode part and the second extending part are bent in a curved shape from the plane direction of the planar shape.

8. The electrostatic transducer according to claim 3, wherein the first counter electrode part, the second counter electrode part, and the dielectric main body constitute an electrostatic laminate, and the electrostatic laminate is formed in a planar shape,
the first terminal electrode part and the first extending part are bent in a curved shape from a plane direction of the planar shape,
the second terminal electrode part and the second extending part are bent in a curved shape from the plane direction of the planar shape, and
the first conductive part and the second conductive part are formed in parallel to the plane direction of the planar shape.

9. The electrostatic transducer according to claim 1, further comprising an insulating sheet covering an entire surface of an outermost layer of the first electrode sheets and the second electrode sheets.

10. The electrostatic transducer according to claim 1, wherein the first counter electrode part, the second counter electrode part, and the dielectric main body constitute an electrostatic laminate, and the electrostatic laminate is formed in a planar shape, and
the electrostatic transducer further comprises:
elastic bodies respectively disposed on two end surfaces that face away from each other in a direction orthogonal to a plane of the planar shape of the electrostatic laminate; and
a cover pressing the electrostatic laminate in a lamination direction and holding the elastic bodies in a state where the elastic bodies are compressed to a greater extent than the electrostatic laminate.

11. The electrostatic transducer according to claim 10, wherein the elastic bodies are respectively disposed on two end surfaces that face away from each other in the direction orthogonal to the plane of the planar shape of the electrostatic laminate and respectively disposed on two end surfaces that face away from each other in the plane direction of the planar shape, and
the cover presses in the plane direction of the electrostatic laminate and holds the elastic bodies in a state where the elastic bodies are compressed to a greater extent than the electrostatic laminate.

12. The electrostatic transducer according to claim 10, wherein an elastic modulus of the elastic body is smaller than an elastic modulus of the electrostatic laminate.

13. The electrostatic transducer according to claim 10, wherein a loss factor tans of the elastic body is equal to or smaller than a loss factor tans of the electrostatic laminate under a predetermined condition.

14. The electrostatic transducer according to claim 1, wherein an outermost layer of the electrostatic laminate composed of the first counter electrode part, the second counter electrode part, and the dielectric main body is formed with an elastic modulus in the lamination direction larger than elastic moduli of other layers.

15. The electrostatic transducer according to claim 14, wherein the outermost layer is a layer surface-modified by UV irradiation.

16. The electrostatic transducer according to claim 2, further comprising:
a first conductive part formed of an elastic deformable material, and the first conductive part being in contact with an end of the first terminal electrode part and an end of the first extending part and being electrically connected to the ends of the first terminal electrode parts; and
a second conductive part formed of an elastic deformable material, and the second conductive part being in contact with an end of the second terminal electrode part and an end of the second extending part and being electrically connected to the ends of the second terminal electrode parts.

17. The electrostatic transducer according to claim 2, wherein the first counter electrode part, the second counter electrode part, and the dielectric main body constitute an electrostatic laminate, and the electrostatic laminate is formed in a planar shape, and
the first terminal electrode part, the second terminal electrode part, the first extending part, and the second extending part extend in a plane direction of the planar shape.

18. The electrostatic transducer according to claim 3, wherein the first counter electrode part, the second counter electrode part, and the dielectric main body constitute an electrostatic laminate, and the electrostatic laminate is formed in a planar shape, and
the first terminal electrode part, the second terminal electrode part, the first extending part, and the second extending part extend in a plane direction of the planar shape.

19. The electrostatic transducer according to claim 2, wherein the first counter electrode part, the second counter electrode part, and the dielectric main body constitute an electrostatic laminate, and the electrostatic laminate is formed in a planar shape,
the first terminal electrode part and the first extending part are bent in a curved shape from a plane direction of the planar shape, and
the second terminal electrode part and the second extending part are bent in a curved shape from the plane direction of the planar shape.

20. The electrostatic transducer according to claim 3, wherein the first counter electrode part, the second counter electrode part, and the dielectric main body constitute an electrostatic laminate, and the electrostatic laminate is formed in a planar shape,
the first terminal electrode part and the first extending part are bent in a curved shape from a plane direction of the planar shape, and
the second terminal electrode part and the second extending part are bent in a curved shape from the plane direction of the planar shape.
